(19) United States
(12) Patent Application Publication
(10) Pub. No.: US 2026/0128541 A1
(43) Pub. Date: May 7, 2026

(54) BOARD-TO-BOARD MECHANICAL CONNECTION CONFIGURATION

(71) Applicant: Aivres Systems Inc., Fremont, CA (US)

(72) Inventor: Tsung Ho CHEN, New Taipei City (TW)

(73) Assignee: Aivres Systems Inc., Fremont, CA (US)

(21) Appl. No.: 19/436,715

(22) Filed: Dec. 30, 2025

(51) Int. Cl. H01R 12/73; H01R 12/72; H01R 13/629; H01R 43/26; H05K 5/02; H05K 7/14

(52) U.S. Cl. CPC H01R 12/737; H01R 12/721; H01R 13/629; H01R 43/26; H05K 5/0291; H05K 7/1418

(57) ABSTRACT

A retention mechanism for installing an expansion card in a computer system comprises at least one ratchet rack mounted in a fixed location in the chassis and a corresponding sliding retainer adapted to slide along the ratchet rack in a vertical direction. The ratchet rack can include a plurality of rack gear teeth and the sliding retainer can include a pawl that is biased into engagement with the rack gear teeth. When the expansion card is inserted into an edge connector socket, the sliding retainer slidingly engages the ratchet rack to linearly move in the vertical direction to contact the expansion card and the pawl is urged into engagement with the rack gear teeth.

### TECHNICAL FIELD

This patent application relates to components for computing systems and, in particular, to a retention mechanism for mechanically connecting and securing an expansion card within a computer system.

### BACKGROUND

Computer systems are assembled from various electronic components and devices that are communicatively interconnected and physically arranged and accommodated in a common chassis or enclosure. The computer systems are often modularly designed for flexibility and scalability to improve or change functionality and the capabilities of the computer system. A common design for modular computer systems is to include one or more expansion sockets located on a printed circuit board such as the motherboard or a dedicated expansion board accommodated internally inside the computer enclosure or chassis. To modify or improve the computer system, additional circuit boards with the appropriate electronic components mounted thereon can be inserted and electrically connected to the connector sockets to communicate and interact with the computer components previously included with the computer system. The new combination expands the functionality of the computer system.

The added circuit boards are typically configured as planar printed circuit cards referred to as expansion cards, daughter boards, or riser cards, and the expansion sockets are configured as elongated edge connectors including a slot to receive an edge of the expansion card. The expansion cards, for example, may be oriented vertically so the cards can be placed into the edge connector sockets in an upright configuration, perpendicular to a horizontally positioned expansion board or motherboard. The orthogonal arrangement of the expansion card and motherboard is referred to as an orthogonal board-to-board connection and advantageously allows for a plurality of expansion cards arranged parallel with one another to be connected to a corresponding plurality of edge connector sockets mounted in parallel on the motherboard. The right-angled connection between the expansion card and the motherboard may benefit from an arrangement or mechanism to assist in retaining the components together.

For example, specific components such as integrated circuits may be mounted to one or more rigid printed boards (PCBs) configured for the routing of electronic data signals and electrical power that may be accommodated within the enclosure. The printed circuit board may include a rigid planar substrate made of an insulative material such as phenolic resin having electrically conductive traces disposed on the planar surfaces or embedded in the laminated structure of the board. Electronic devices mounted to the planar surface of the printed circuit board are communicatively connected by the conductive traces. The arrangement and cooperative operation of the electronic components are responsible for the computational and processing functionality of the computer system.

Typically, multiple printed circuit boards having different electronic components arranged for different purposes may be installed in the same chassis and must communicate electronically with one another. Although communication can be established by wires and cables, sometimes it is desirable to physically connect two printed circuit boards directly together, eliminating wires and improving electronic communication. Direct physical connection between printed circuit boards communicatively links the local communication busses thereon improving the transfer of data signals and electrical power. Various orientations and arrangements are available for directly connecting two or more printed circuit boards together. For example, two printed circuit boards can be oriented orthogonally at right angles and thus perpendicularly intersect each other. Right angled connectors or edge connectors can be used to communicatively interface the orthogonal boards. In another example, two printed circuit boards can be placed in a parallel, spaced apart orientation. Such a board-to-board arrangement may be referred to a parallel stacked or mezzanine arrangement

### SUMMARY OF THE DISCLOSURE

To install and retain one or more expansion cards internally in a computer system, the disclosure describes a retention mechanism assembled from a plurality of interacting components configured for generating and applying retaining forces upon the expansion cards. The retention mechanism includes a ratchet rack that is adapted to be mounted to a fixed location in a chassis of the computer system. The ratchet rack includes a plurality of rack gear teeth linearly aligned in a vertical direction of the chassis. The retention mechanism also includes a sliding retainer that can slide along the ratchet rack in the vertical direction and that is adapted to contact the expansion card. The sliding retainer includes a lever arm with a pawl urged into engagement with the plurality of rack gear teeth to selectively lock the sliding retainer along the vertical direction.

In another aspect, the sliding retainer includes a card channel for receiving a rear card edge of expansion card.

In another aspect, the card channel protrudes in a longitudinal direction perpendicular to the vertical direction.

In another aspect, the sliding retainer comprises a retainer foot adapted to abut the expansion card in the vertical direction.

In another aspect, the ratchet rack and the sliding retainer are coupled together by a linear bearing.

In another aspect, the ratchet rack is located on a ratchet panel having a planar shape.

In another aspect, the linear bearing comprises a rail structure and the sliding retainer comprises a saddle block that slidingly couples to the rail structure.

In another aspect, the rail structure comprises a flange offset from a forward surface of the ratchet panel and the saddle block includes a saddle catch configured to be received between the flange and the forward surface of the ratchet block.

In another aspect, the lever arm is pivotally connected to the saddle block by a living hinge.

In another aspect, the lever arm comprises a finger pull latch adapted to rotate the lever arm with respect to the living hinge to release the pawl from the plurality of ratchet gear teeth.

In another aspect, the lever arm is pivotally connected to the saddle block at a pivot axis perpendicular to the vertical axis.

In another aspect, the ratchet panel comprises a plurality of ratchet racks and the sliding retainer comprises a saddle block adapted to slidingly couple to the plurality of ratchet racks.

In another aspect, the ratchet panel comprises an upper stop and a lower stop constraining vertical travel of the sliding retainer.

In another aspect, the upper stop comprises a cantilevered depressible with respect to a forward surface of the ratchet panel.

The disclosure also describes a method of installing an expansion card into an edge connector socket in a computer system by fixedly securing a ratchet rack in a chassis of the computer system. The ratchet rack includes a plurality of ratchet gear aligned in a vertical direction associated with the chassis. The method includes inserting a lower card edge of the expansion card in the vertical direction into the edge connector socket and slidingly engaging a sliding retainer to the ratchet rack. The sliding retainer is slide in the vertical direction to contact the expansion card. To lock the sliding retainer with respect to the ratchet rack, the method includes urging a pawl on the sliding retainer into engagement with the plurality of rack gear teeth on the ratchet rack.

In another aspect, the pawl is urged into engagement by a living hinge on the sliding retainer.

In another aspect, the method includes uninstalling the expansion card by pivoting the living hinge to release the pawl from the plurality of rack gear teeth.

The disclosure also describes a retention mechanism for retaining a plurality of expansion cards to a corresponding plurality of edge connector socket in a computer system. The retention mechanism includes a ratchet panel comprising including a plurality of ratchet racks, of the plurality of ratchet rack each comprising a plurality of rack gear teeth aligned linearly in a vertical direction associated with a chassis of the computer system. The plurality of ratchet racks may be spaced apart in a lateral direction perpendicular to the vertical direction. The retention mechanism also includes one or more sliding retainers each adapted to slide in the vertical direction along a pair of ratchet racks adjacent to each other. The sliding retainers each include a pawl urged to engage with the rack gear teeth on the pair of ratchet racks to lock the sliding retainer in the vertical direction.

In another aspect, each sliding retainer comprising a pair of card channels, each card channel adapted to receive a rear card edge of a corresponding expansion card.

In another aspect, each sliding retainer comprises a retainer foot adapted to abut the expansion card in the vertical direction

A possible advantage of the disclosure is that the retention mechanism can stabilize and secure one or more expansion cards within a computer system to resist vibrations and shocks that may attempt to disconnect the expansion cards. A related advantage is that the retention mechanism can be used without tools or fasteners simplifying installation and use. These and other advantages and features will be apparent from the foregoing detailed description and accompanying drawings.

### BRIEF DESCRIPTION OF THE DRAWINGS

FIG. 1 is a perspective view of a computer system having an enclosure or chassis accommodating internal computer components such as a plurality of expansion cards connectable to corresponding edge connector sockets on an expansion board.

FIG. 2 is a perspective view of a retention mechanism including a ratchet panel configured to be fixedly secured in the computer system and a plurality of sliding retainers adapted to slide with respect to the rachet panel to releasably retain the expansion cards.

FIG. 3 is a top plan view of the sliding retainer having a saddle block that is coupled with a rail structure associated with the ratchet panel.

FIG. 4 is a cross-sectional view of a sliding retainer securely engaged with a ratchet rack by a pawl urged to catch one of the plurality of rack gear teeth.

FIG. 5 is a cross-sectional view of the sliding retainer pivoted with respect to the ratchet rack to release the pawl from the plurality of rack gear teeth.

FIG. 6 is perspective assembly view of retention mechanism retaining the rearward card edges of the expansion cards within the corresponding edge connector sockets by sliding the sliding retainers with respect to the ratchet racks on the ratchet panel.

FIG. 7 is a perspective view of an example of the retention mechanism configured to retain the forward card edges of the expansions cards to the computer system.

### DETAILED DESCRIPTION

The following detailed description is exemplary in nature and is not intended to limit the disclosure or the application and uses of the described embodiments. Furthermore, there is no intention to be bound by any expressed or implied theory presented in the preceding background, summary and brief description of the drawings, or the following detailed description. Numerous specific details are set forth in order to provide a more thorough understanding of the disclosed technology. However, it will be apparent to one of ordinary skill in the art that the disclosed technology may be practiced without these specific details. In other instances, well-known features have not been described in detail to avoid unnecessarily complicating the description.

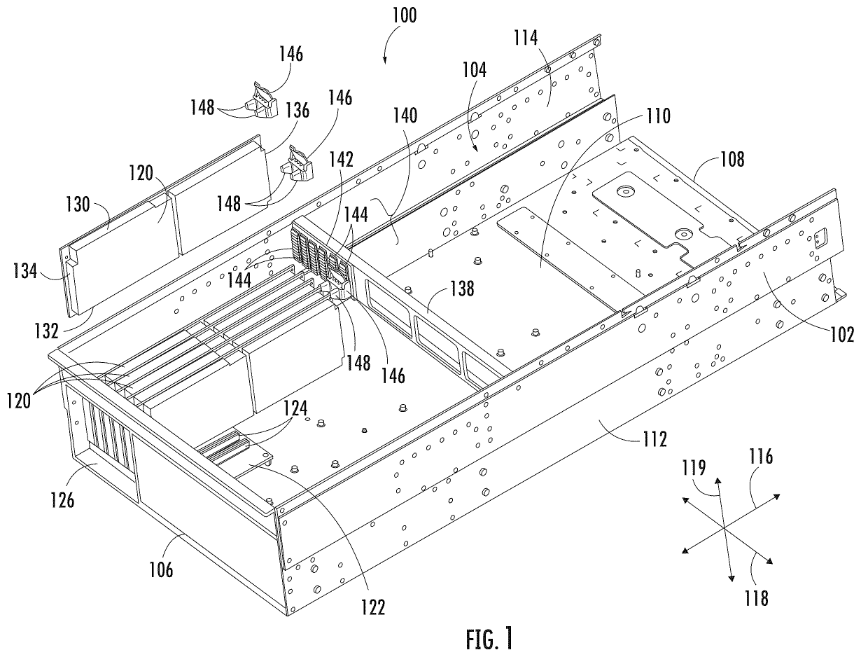

Now referring to the drawings, where whenever possible like reference numbers will refer to like elements, there is illustrated in FIG. 1 a computer system 100 comprised of various electronic devices and hardware that are cooperatively interconnected and assembled together and that may be accommodated in an enclosure or chassis 102, as shown with the chassis cover removed. The chassis 102 can be a box-like structure made of formed sheet metal or molded plastic and that defines an internal space or chassis volume 104 for the internal computer components and electronic hardware of the computer system 100. The computer system 100 can be configured for communicative integration with a larger network or system and the chassis 102 may be designed with standardized dimensions for mounting into a rack with similar computer systems, although in other instances the computer system 100 may be a standalone configuration.

The chassis 102 can accommodate components and hardware devices like central processing units, memory modules, hard drives, power convertors, and fan units for circulating air internally about the chassis volume 104 for cooling of the internal components. The chassis 102 may be rectangular and box-like in shape and can extend between a front panel 106 and rear face 108 that are parallel to each other and located opposite one another. The terms “front” and “rear” are for reference though and generally arbitrary. To complete the box-like structure, the chassis 102 can also include a bottom panel 110 that forms the planar floor of the computer system 100 and first and second upright sidewalls 112, 114 extending perpendicularly from the bottom panel 110. A removable cover may also be included to enclose the chassis volume 104. The chassis panels and walls can be structurally connected together for rigidity so the chassis 102 may support the internal hardware components. The front panel 106 and rear face 108 may accommodate various LED indicator lights, activation and setting buttons and switches, ports and sockets for data and power communications, and other features for interfacing with operators and other systems.

For reference purposes, the spatial arrangement of the chassis 102 can be associated with a longitudinal direction 116 that extends perpendicularly between the parallel arrangement of the front panel 106 and the rear face 108. The chassis 102 can also define a lateral direction 118 that is orthogonal to the longitudinal direction 116 and that is generally directed between the parallel arrangement of the first and second upright sidewalls 112, 114. The longitudinal and lateral directions 116, 118 may perpendicularly intersect and define a horizontal plane of the chassis volume 104. A vertical direction 119 can be oriented perpendicular to the horizontal plane defined by the longitudinal and lateral directions 116, 118 and can be associated with the vertical height of the chassis 102.

To expand the functionality of the computer system 100, one or more expansion cards 120 can be selectively included when desired and can be internally accommodated inside the chassis volume 104. The installable expansion cards 120, also referred to as PCI extension cards, adapter cards, riser cards and the like, may be planar circuit boards (PCBs) having additional electronic devices and circuitry mounted thereon and configured for the routing of electronic data signals and electrical power. The mounted devices may be integrated circuits such as memory expansion modules, specialized processing units, communications and interface circuits, etc. In a specific example, the expansion card 120 can include one more graphics processing units (GPUs) that are designed for applications such as image processing, data analytics, artificial intelligence, and other high-performance computing applications.

The printed circuit boards forming the expansion cards 120 may comprise a rigid planar substrate made of an insulative material such as phenolic resin having electrically conductive traces disposed on the planar surfaces or embedded in the laminated structure of the board communicatively connecting the mounted devices. The arrangement and cooperative operation of the electronic components on the expansion cards 120 are responsible for the computational and processing functionality of the computer system 100.

To connect with the expansion cards 120, the computer system 100 can include an expansion board 122 located in the chassis volume 104 and fixed to the chassis 102. The expansion board 122 can also be a planar printed circuit board spatially supported parallel to the horizontal plane defined by the longitudinal and lateral directions 116, 118. The expansion board 122 can include a plurality of expansion slots configured as edge connector sockets 124 into which the expansion cards 120 may be plugged. The edge connector sockets 124 are configured as elongated slots aligned with the longitudinal direction 116. The expansion cards 120 can be inserted into the edge connector sockets 124, which may include spring loaded contacts that bias against corresponding conductive traces on the surfaces of the expansion card to establish electronic communication between the components. The plurality of edge connector sockets 124 can be arranged in parallel to each other and laterally spaced apart in the lateral direction 118.

To access the expansion cards 120, the chassis 102 can include a plurality of expansion bays 126 that are formed as openings in the forward panel 106 for example. The expansion bays 126 can be arranged in the lateral direction 118 and correspondingly aligned with respective edge connector sockets 124 on the expansion board 122. The openings associated with the expansion bays 126 enable the expansion cards 120 to form electrical connections with external cables, plugs, and the like. In the described arrangement, the expansion board 122 is located adjacent to the forward panel 106 of the chassis 102, although other spatial configurations and arrangements are possible.

In general, the expansion cards 120 can have a rectangular or orthogonal shaped planar configuration including an upper card edge 130 and a parallel lower card edge 132 that is adapted to be inserted into the edge connector socket 124 on the expansion board 122. The lower card edge 132 can be configured as an edge connector and may include a plurality of conductive traces that are exposed thereon to make electrical contact with corresponding conductive spring-loaded contacts in the edge connector socket 124 when the expansion card 120 is inserted and installed. When the expansion card 120 is installed in the chassis 102, the upper and lower card edges 130, 132 are aligned parallel with the longitudinal direction 116 of the computer system 100.

The expansion card 120 can include a forward card edge 134 and a parallel rearward card edge 136 that are orthogonal to the upper and lower card edges 130, 132 and that may be aligned in the vertical direction 119. When the expansion card 120 is installed, the forward card edge 134 may be situated adjacently with respect to an expansion bay 126 of the front panel 106. In an embodiment, the rearward card edge 136 may be oriented toward the rear face 108 of the chassis 102. To support the rigid structure of the chassis, a support brace 138 can be installed between the first and second upright sidewalls 112, 114 and traverse the longitudinal direction 116 and may be located to pass adjacently to the rearward card edges 136 when installed. Terms such as forward and rearward are used throughout the specification for reference purposes and form no limitation on the scope of the subject matter.

To retain the expansion cards 120 in connection with the edge connector sockets 124 after installation, the computer system 100 can be associated with a retention mechanism 140 that operatively engages the expansion cards 120 to stabilize and spatially fix their location within the chassis volume 104. For example, because the expansion cards 120 are physically connected along the lower card edge 132 to the edge connector sockets 124, the expansion cards are susceptible to vibrations especially during installation of the computer system 100. The retention mechanism 140 is configured to physically contact and hold the expansion cards 120 advantageously without the use of tools or mechanical fasteners. The retention mechanism 140 can also be releasable to simplify removal of the expansion cards 120 during upgrades.

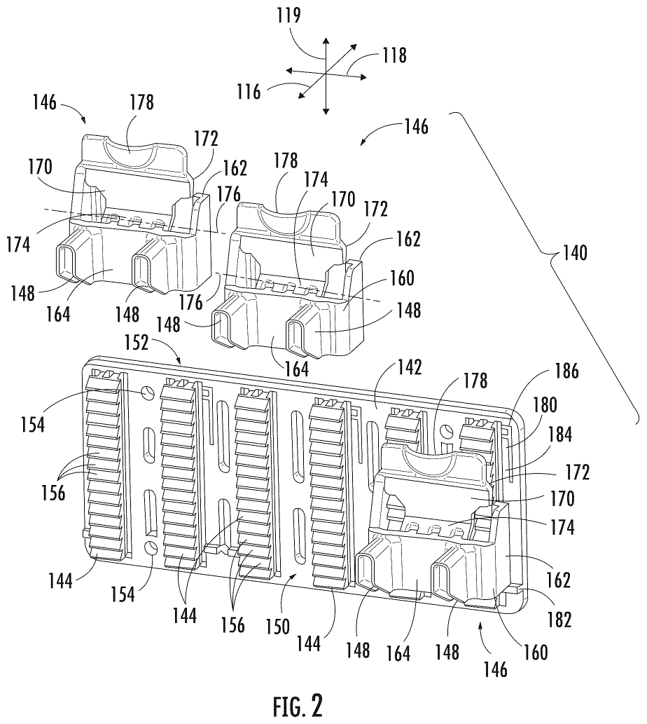

Referring to FIGS. 1 and 2, the retention mechanism 140 can be a multicomponent assembly including a ratchet panel 142 that includes a one or more ratchet racks 144 that cooperatively interact with one or more sliding retainers 146. In an embodiment, a plurality of ratchet racks 144 can be aligned parallel to each other and disposed on the ratchet panel 142 to engage with the plurality of sliding retainers 146 to thereby connect with several of the expansion cards 120 that may be included in the computer system 100. In an embodiment, the sliding retainers 146 can include one or more card channels 148 that are shaped to physically receive a corner of the expansion cards 120 formed by the intersection of the upper card edge 130 and the rearward card edge 136. To achieve the geometry of the ratchet panel 142 and the sliding retainer 146, the components of the retention mechanism may be made from injection molded plastic.

In operation, the ratchet panel 142 can be fixedly mounted on the support brace 138 for location proximate to the rearward card edges 136. The plurality of ratchet racks 144 on the ratchet panel 142 are orientated in the vertical direction 119 and are spaced parallel with respect to the lateral direction 118. The sliding retainers 146 can slidingly engage the plurality of ratchet racks 144 to move downwardly with respect to the vertical direction 119. As the sliding retainers 146 move downwardly with respect to the ratchet panel 142, the card channel 148 can receive and physically constrain the rear card edges 136 thereby stabilizing the expansion cards 120 in the lateral and vertical directions 118, 119. To remove expansion cards, the sliding retainers 146 are configured to physically disengage with the ratchet racks 144 to be released from the ratchet panel 142.

Referring to FIG. 2, the ratchet panel 142 corresponds to the component of the retainer mechanism 140 that is configured to be fixedly secured with respect to the chassis of the computer system 100. The ratchet panel 142 can be a planar orthogonal panel having a forward surface 150 and a parallel rearward surface 152 that is adapted for mounting to a corresponding structure in the chassis 102, such as the support brace 138. The mounting arrangement in FIG. 1 is exemplary though and the ratchet panel 142 may be fixedly mounted to other suitable structures in the chassis 102. To fixedly mount the ratchet panel 142 using fasteners, for example, a plurality of fastener apertures 154 can be disposed between the forward and rearward surface 150, 152 and dimensioned to accommodate a bolt or screw.

The plurality of ratchet racks 144 can be physically formed on the forward face 150 of the ratchet panel 142 and project outwardly in the longitudinal direction 116. The ratchet racks 144 can be configured as linear gears each have a plurality of rack gear teeth 156 that are oriented parallel with the lateral direction 118 and spaced with respect to the vertical direction 119. The rack gear teeth 156 can be shaped as triangular saw-toothed teeth but other geometries may be used. The ratchet racks 144 extend in the vertical direction 119 and established a range of vertical travel for the sliding retainers 146.

In the illustrated example, the ratchet panel 142 may have two ratchet racks 144 operatively associated with an individual sliding retainer 146. The two-to-one correspondence is an example though and a single ratchet rack 144 can be operatively associated with a single sliding retainer 146. Moreover, the illustrated example of the ratchet panel 142 may have a number of ratchet racks 144 to engage with three sliding retainers 146 but any suitable quantity of racks and retainers may be included with the retention mechanism 140. In an embodiment, the plurality of ratchet racks 144 can be directly and individually mounted to the chassis and the ratchet panel 142 can be omitted.

The sliding retainers 146 can each include two card channels 148 that protrude in the longitudinal direction 116 and that are each shaped to accommodate an expansion card. For example, each card channel 148 may be shaped as a three-sided structure that defines a gap or spacing that is dimensioned to correspond with and fit to the width of a corresponding expansion card. The lateral distance between the two card channels 148 can correspond to the lateral spacing between adjacent expansion cards after installation. The inclusion of two card channels 148 per sliding retainer 146 is by way of example and fewer or greater numbers may be utilized.

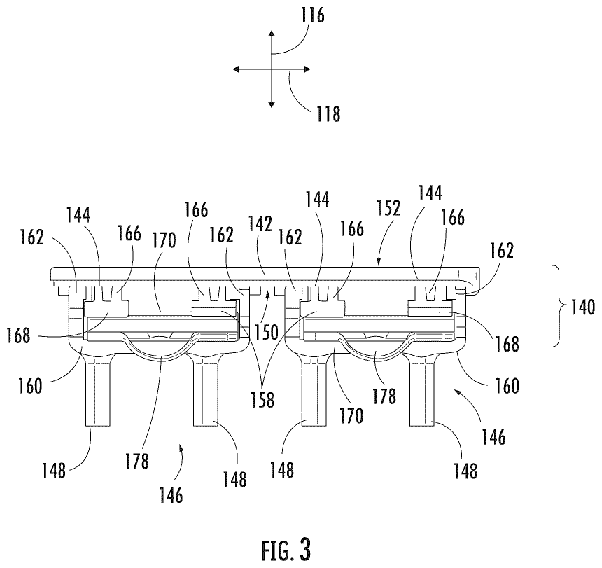

To couple the sliding retainer 146 to the ratchet panel 142, the structural components can be configured to form a linear bearing or slide mechanism that allows relative vertical travel in the vertical direction 119. For example, referring to FIG. 3, the sliding retainer 146 can be partly formed as a saddle block 160 from which the card channels 148 protrude. The saddle block 160 can be a C-shaped structure having a pair of saddle catches 162 that are spaced apart in the lateral direction 118 and that extend perpendicularly from a saddle web 164.

To cooperate with the saddle catches 162, each of the ratchet racks 144 can be formed as a T-shaped beam 166 having a flange 168 offset from and parallel to the forward face 150 of the ratchet panel 142. In a possible example, the T-shaped beams 166 of a pair of adjacent ratchet racks 144 can cooperate to form a rail structure for coupling with the saddle block 160. For example, the spatial gap between the flange 168 and the forward surface 150 of the ratchet panel 142 is configured to receive inwardly directed hooks on the distal end of the saddle catches 162 to enable relative movement between the saddle block 160 and the ratchet panel 142 while coupling the components together.

Referring back to FIG. 2, to selectively lock and fix the sliding retainer 146 with respect to the ratchet racks 144 on the ratchet panel 142, the sliding retainers can include a lever arm 170 associated with a pawl 172. The lever arm 170 can be pivotally connected to the saddle block 160 by a living hinge 174 that allows the lever arm 170 to be articulated forwardly and rearwardly with respect to the longitudinal direction 116. The living hinge 174 is flexible to allow pivotal movement between the lever arm 172 and the rigid structure of the saddle block 160. The living hinge 174 establishes a pivot axis 176 that is orthogonal to the longitudinal axis 116. The living hinge 174 can be resiliently biased to urge the lever arm 170 into a vertically upright position and adjacent against the ratchet racks 144 protruding from the ratchet panel 142. In other examples, the living hinge 174 can be replaced by another pivotal connection such as a revolute joint or pin hinge that may be spring loaded to bias the lever arm into the vertically upright position.

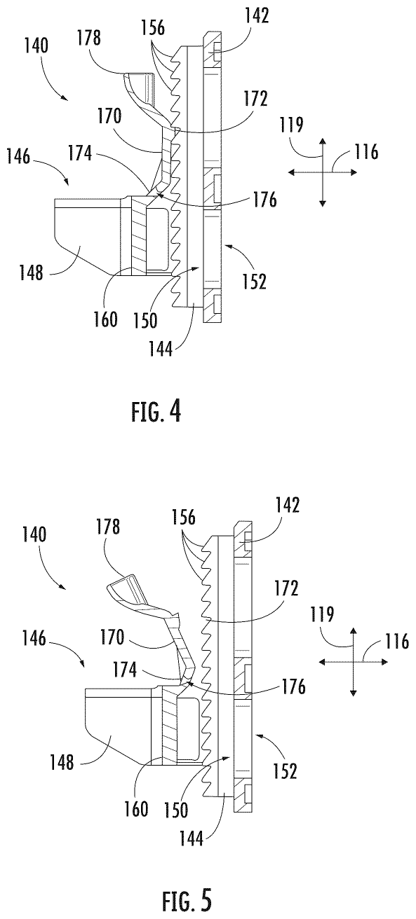

Referring to FIGS. 4 and 5, the pawl 172 can be formed as a hook or barb on the inner surface of the lever arm 170 and that is adapted to mate with the plurality of rack gear teeth 156. For example, the pawl 172 and the saw-tooth shapes of the ratchet gear teeth 156 are oriented so that that pawl 172 can slide over the rack gear teeth 156 when the sliding retainer 146 is moved downward in the vertical direction 119 with respect to the ratchet racks 148. When the sliding retainer 146 is moved vertically upwards, the pawl 172 catches with an individual one of the rack gear teeth 156 thereby arresting further movement in the vertical direction 119.

To release the pawl 172 from the ratchet gear teeth 156, the lever arm 170 can be partly formed at the distal end with a finger pull latch 178. For example, the finger pull latch 178 of the lever arm 170 can be grasped by fingers and pulled forwardly in the longitudinal direction 116 to pivot the lever arm 170 with respect to the pivot axis 176. The force applied to the finger pull latch 178 can be sufficient to overcome the spring biasing force associated with the living hinge 174. Forward pivotal movement of the lever arm 170 with respect to the ratchet panel 142 removes the pawl 172 from contact with the ratchet gear teeth 156. The sliding retainer 146 is thereafter free to move in the vertical direction 119 with respect to the ratchet racks 144.

Referring back to FIG. 2, the retainer mechanism 140 can be configured with additional functional features effecting relative motion of the ratchet panel 142 and sliding retainer 146. For example, to prevent the sliding retainer from unintentionally decoupling, the ratchet panel 142 can be configured with an upper stop 180 and the lower stop 182 that constrain the vertical travel of the sliding retainer 146. The lower stop 182 can be configured as a bump or flange protruding from the forward surface 150 of the ratchet panel 150 proximately adjacent to the lower end of one of the ratchet racks 148. The upper stop 180 can be configured as a cantilevered arm 184 that is depressible with respect to the forward surface 150 of the ratchet panel 150 and that includes a distal barb 186 at an upper end. The cantilevered arm 184 is aligned in the vertical direction 119 and is parallel to and adjacent with the respective ratchet rack 144.

During assembly, the sliding retainer 146 can be moved downwardly in the vertical direction 119 with respect to the ratchet racks 144 so that saddle block 160 contacts the distal barb 186 and depresses the cantilevered arm 184 with respect to the forward surface 150 of the ratchet panel 142. Displacement of the cantilevered arm 184 allows vertical travel of saddle block 160 past the distal barb 186 until the cantilevered arm 184 is able to recover its position with respect to the forward surface 150. The lower limit of travel of the saddle block 160 in the vertical direction is limited by the lower stop 182. Movement of the sliding retainer 146 is constrained with respect to the vertical direction by the upper and lower stops 180, 182 between which the saddle block 160 is trapped.

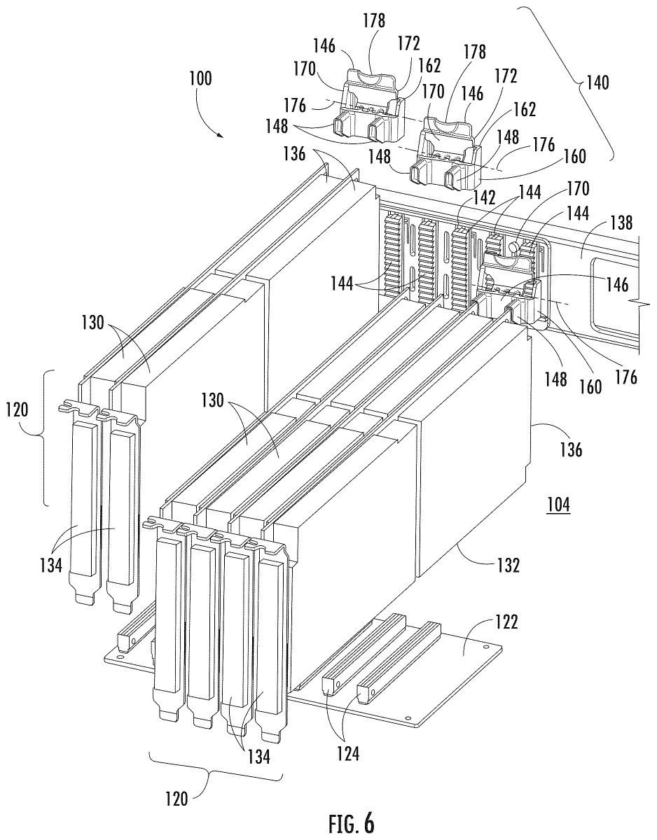

Referring to FIG. 6, there is illustrated a process for installing and retaining a plurality of expansion cards 120 to an expansion board 122 in accordance with the disclosure. The ratchet panel 142 may have been previously mounted to a support brace 138 or to another fixed location in the chassis volume 104. When the ratchet panel 142 is mounted, it may be in a fixed spatial location with respect to the expansion board 122 and the plurality of edge connector sockets 124 located thereon. The plurality of ratchet racks 144 on the ratchet panel 142 are aligned linearly parallel with the vertical direction 119.

The expansion cards 120 can be aligned vertically over the edge connector sockets 124 and can be installed by moving downward in the vertical direction 119 so that the lower card edge 132 is inserted into the corresponding edge connector socket 124 to establish an electrical and mechanical connection. In the illustrated arrangement, the rear card edge 136 may be located proximate to the support brace 138 and to the ratchet panel 142 mounted thereon. If necessary to accommodate expansion cards 120 of different longitudinal lengths, the location of the support brace with the ratchet panel 142 may be moved along the longitudinal direction 116, or the thickness of the ratchet panel 142 may be adjusted. The plurality of expansion cards 120 may become generally aligned in the longitudinal direction 116 with the corresponding plurality of ratchet racks 144.

To fixedly retain the expansion cards 120 to the expansion board 122, the sliding retainers 146 are aligned in the longitudinal and lateral directions 116, 118 with the corresponding expansion card 120 and moved vertically downward to slidingly couple with the ratchet racks 144. For example, the saddle catches 162 formed on the saddle block 160 can be received between the flanges 168 associated with the ratchet racks 144 and the forward surface 150 of the ratchet panel 142. The sliding retainers 146 can be moved downward in the vertical direction 119 so that the card channels 148 receive rear card edge 136 of a corresponding expansion card 120. By capturing the rear card edge 136 in the card channel 148, the expansion card 120 is stabilized in the lateral and vertical directions 118, 119 and the lower card edge 132 can be prevented from disconnecting with the edge connector socket 124.

To secure installation of the expansion cards 120, referring to FIG. 4, the pawl 172 may mate with an individual one of the rack gear teeth 156 on the ratchet rack 144. For example, the living hinge 174 may be biased to urge the lever arm 170 into the upright position against the ratchet panel 142 so that the pawl 172 is fixedly caught by the corresponding rack gear teeth 156. By providing a plurality of rack gear teeth 156 on the ratchet rack 144, the position of the sliding retainer with respect to the vertical direction can be selectively adjusted and the retainer mechanism 140 can cooperate with expansion cards of varying vertical heights.

To remove an expansion card 120, referring to FIG. 5, the lever arm 170 can be pivoted with respect to the pivot axis 176 longitudinally forward and away from the ratchet panel 142. For example, the finger pull latch 178 can be articulated to overcome the spring biasing force of the living hinge 174 and pivot the lever arm 170 so that the pawl 172 is removed from between the rack gear teeth 156. Referring to FIG. 6 again, the sliding retainer 146 is free to slide in the vertical direction 119 with respect to the ratchet racks 144 until the sliding retainer is released from the ratchet panel 142. The card channels 148 release the rear card edges 136 so that the expansion cards 120 can be disconnected from the corresponding edge connector sockets 124.

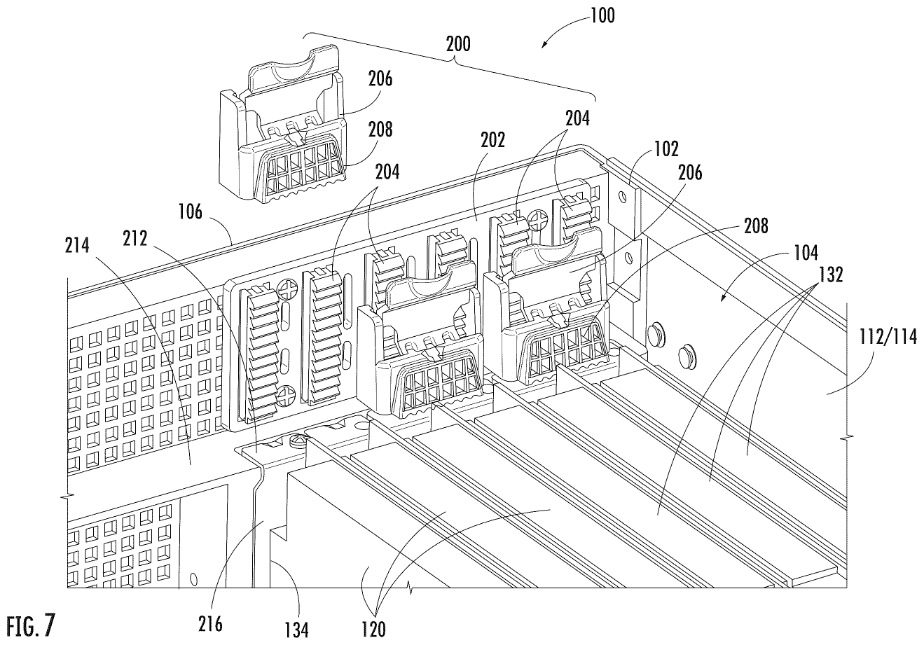

Referring to FIG. 7, there is illustrated another example of a retainer mechanism 200 to retain the expansion cards 120 along the forward card edge 134. The retainer mechanism 200 is similar to the first example and includes a ratchet panel 202 having a plurality of ratchet racks 204 that are parallel and aligned with the vertical direction 119. The ratchet panel 202 can be mounted to the interior side of the front panel 106 of the computer chassis 102 to be positioned proximate the forward card edges 132.

The retainer mechanism 200 can also include a sliding retainer 206 that is adapted to couple the plurality of ratchet racks 204 on the ratchet panel 202. For example, the sliding retainer 206 may include a saddle block and saddle catches and the ratchet racks 204 can be configured to form a rail structure as described above so that the components can move with respect to each other in the vertical direction 119. As also described above, the sliding retainer 206 can also include a lever arm and pawl that are adapted to mate with the plurality of rack gear teeth on the ratchet racks 204.

To engage the expansion cards 120, however, the sliding retainer 206 can include a retainer foot 208 that is adapted for abutting contact with the expansion cards. For example, each of the expansion cards 120 can be associated with a card bracket 210 that is connected to and extends along the front card edge 134. Each card bracket 210 can be a metal component and can be configured to align the front card edge 134 with the expansion bays 126 located in the front panel 106 of the chassis 102. The card brackets 210 can each include a bracket tab 212 that extends perpendicularly and is positioned at a right angle to the front card edges 134.

The bracket tabs 212 can abut against a horizontal ledge 214 that is included on the inner side of the front panel 106. The horizontal ledge 214 can extend in the lateral direction 118 between the first and second upright sidewalls 112, 114. The ratchet panel 202 can be located vertically above the horizontal ledge 214 and longitudinally forward of the bracket tabs 212 situated thereon.

When the sliding retainer 206 is caused to slide downwardly along the ratchet racks 204 in the vertical direction 119, the retainer foot 208 abuts against the bracket tabs 212 situated along the horizontal ledge 214. For example, because the ratchet racks 204 protrude from the ratchet panel 202 longitudinally rearward and the sliding retainer 206 is similarly offset from the front panel 106 in the longitudinal direction 116, the retainer foot 208 is positioned vertically over the bracket tabs 212. In an example, the retainer foot 208 can have a width in the lateral direction 118 that extends across two more bracket tabs 212 associated with two adjacent expansion cards 120, although the number of expansion cards and associated sliding retainers may vary.

The bracket tabs 212 may be held against the horizontal ledge 214 without the need of fasteners or other tools by the retainer foot 208. To remove an expansion card 120, the sliding retainer 206 can moved vertically upward with respect to the ratchet racket 204, for example, by pivoting the finger pull latch, and thereby release the bracket tabs 212 from the horizontal ledge 214.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A retention mechanism for installing an expansion card into an edge connector socket in a computer system comprising:
a ratchet rack adapted to be mounted to a fixed location in a chassis of the computer system, the ratchet rack comprising a plurality of rack gear teeth linearly aligned in a vertical direction associated with the chassis; and
a sliding retainer slidably along the ratchet rack in the vertical direction and adapted to contact the expansion card, the sliding retainer comprising a lever arm with a pawl urged into engagement with the plurality of rack gear teeth to selectively lock the sliding retainer along the vertical direction.

2. The retention mechanism of claim 1, wherein the sliding retainer comprises a card channel for receiving a rear card edge of expansion card.

3. The retention mechanism of claim 2, wherein the card channel protrudes in a longitudinal direction perpendicular to the vertical direction.

4. The retention mechanism of claim 1, wherein the sliding retainer comprises a retainer foot adapted to abut the expansion card in the vertical direction.

5. The retention mechanism of claim 1, wherein the ratchet rack and the sliding retainer are coupled by a linear bearing.

6. The retention mechanism of claim 5, wherein the ratchet rack is located on a ratchet panel having a planar shape.

7. The retention mechanism of claim 6, wherein the linear bearing comprises a rail structure and the sliding retainer comprises a saddle block that slidingly couples to the rail structure.

8. The retention mechanism of claim 7, wherein the rail structure comprises a flange offset from a forward surface of the ratchet panel and the saddle block comprises a saddle catch configured to be received between the flange and the forward surface of the ratchet block.

9. The retention mechanism of claim 7, wherein the lever arm is pivotally connected to the saddle block by a living hinge.

10. The retention mechanism of claim 9, wherein the lever arm comprises a finger pull latch adapted to rotate the lever arm with respect to the living hinge to release the pawl from the plurality of ratchet gear teeth.

11. The retention mechanism of claim 6, wherein the lever arm is pivotally connected to the saddle block at a pivot axis perpendicular to the vertical axis.

12. The retention mechanism of claim 7, wherein the ratchet panel comprises a plurality of ratchet racks and the sliding retainer comprises a saddle block adapted to slidingly couple to the plurality of ratchet racks.

13. The retention mechanism of claim 6, wherein the ratchet panel comprises an upper stop and a lower stop constraining vertical travel of the sliding retainer.

14. The retention mechanism of claim 13, wherein the upper stop comprises a cantilevered arm depressible with respect to a forward surface of the ratchet panel.

15. A method of installing an expansion card into an edge connector socket in a computer system comprising:
fixedly securing a ratchet rack internally in a chassis of the computer system, the ratchet rack comprising a plurality of ratchet gear aligned in a vertical direction associated with the chassis;
inserting a lower card edge of the expansion card in the vertical direction into the edge connector socket;
slidingly engaging a sliding retainer to the ratchet rack and sliding the sliding retainer in the vertical direction to contact the expansion card; and
urging a pawl on the sliding retainer into engagement with the plurality of rack gear teeth on the ratchet rack to lock the sliding retainer in the vertical direction.

16. The method of claim 15, wherein the pawl is urged into engagement by a living hinge on the sliding retainer.

17. The method of claim 15, further comprising uninstalling the expansion card by pivoting the living hinge to release the pawl from the plurality of rack gear teeth.

18. A retention mechanism for retaining a plurality of expansion cards to a corresponding plurality of edge connector socket in a computer system, the retention mechanism comprising:
a ratchet panel comprising a plurality of ratchet racks, of the plurality of ratchet rack each comprising a plurality of rack gear teeth aligned linearly in a vertical direction associated with a chassis of the computer system, the plurality of ratchet racks spaced apart in a lateral direction perpendicular to the vertical direction; and
one or more sliding retainers, each sliding retainer adapted to slide in the vertical direction along a pair of ratchet racks adjacent to each other, each sliding retainer comprising a pawl urged to engage with the rack gear teeth on the pair of ratchet racks to lock the sliding retainer in the vertical direction.

19. The retention mechanism of claim 18, wherein each sliding retainer comprising a pair of card channels, each card channel adapted to receive a rear card edge of a corresponding expansion card.

20. The retention mechanism of claim 18, wherein each sliding retainer comprises a retainer foot adapted to abut the expansion card in the vertical direction.
